(19) United States
(12) Patent Application Publication
(10) Pub. No.: US 2025/0048773 A1
(43) Pub. Date: Feb. 6, 2025

(54) SYSTEM FOR STABILIZING AND/OR IMPROVING AN EFFICIENCY OF A SOLAR CELL, AND METHOD FOR STABILIZING AND/OR IMPROVING AN EFFICIENCY OF A SOLAR CELL

(71) Applicant: HANWHA Q CELLS GMBH, Bitterfeld-Wolfen (DE)

(72) Inventors: Ansgar METTE, Bitterfeld-Wolfen (DE); Fabian FERTIG, Bitterfeld-Wolfen (DE); Stefan HÖRNLEIN, Bitterfeld-Wolfen (DE)

(21) Appl. No.: 18/716,724

(22) PCT Filed: Dec. 8, 2022
(86) PCT No.: PCT/DE2022/100924

§ 371 Date: Jun. 5, 2024

(30) Foreign Application Priority Data
Dec. 8, 2021 (DE) 10 2021 132 240.5

(51) Int. Cl. H01L 31/18

(52) U.S. Cl. CPC H01L 31/1864

(57) ABSTRACT

A system for stabilizing and/or improving an efficiency of a solar cell having a front-side front contact and a rear-side rear contact. The system includes: an illumination unit that is designed to locally illuminate the solar cell; a voltage source having two contacting apparatuses, wherein one contacting apparatus is designed to be connected to the front contact of the solar cell, and the other contacting apparatus is designed to be connected to the rear contact of the solar cell in such a way that a current flow is induced in the reverse direction of the solar cell. The system also includes a heating apparatus which is designed and configured to heat the solar cell during a current flow induced in the reverse direction.

### RELATED APPLICATIONS

The present application is a National Phase entry of PCT Application No. PCT/DE2022/100924, filed Dec. 8, 2022, which claims priority to German Patent Application No. 10 2021 132 240.5, filed Dec. 8, 2021, the disclosures of which are hereby incorporated by reference herein in their entirety.

### FIELD OF THE INVENTION

The invention relates to a system for stabilizing and/or improving an efficiency of a solar cell and to a method for stabilizing and/or improving an efficiency of a solar cell. In particular, the invention relates to a system for stabilizing and/or improving an efficiency of a solar cell having a front-side front contact and a rear-side rear contact, wherein the system comprises an illumination unit that is designed to locally illuminate the solar cell, and a voltage source having two contacting apparatuses, wherein one contacting apparatus is designed to be connected to the front contact of the solar cell, and the other contacting apparatus is designed to be connected to the rear contact of the solar cell in such a way that a current flow is induced in the reverse direction of the solar cell. The invention also relates to a method that comprises the method steps of: applying a voltage to the provided solar cell in the reverse direction and locally illuminating and scanning the front side of the solar cell to which the voltage is applied in such a way that a current flow flows through the solar cell in the reverse direction.

### BACKGROUND OF THE INVENTION

This method is referred to as LECO (laser enhanced contact optimization), because in particular it improves the electrical contact between the front-side electrode and the underlying semiconductor material of the solar cell. The contacts of the solar cells are often produced by means of paste metallization and subsequent firing. After contact has been formed by excessively fast firing, solar cells are often not in their optimal state in terms of their lifetime of mass recombination, surface recombination speed, and the contact resistance between metal and semiconductor. The LECO method is able to improve the suboptimal contact resistance.

DE 10 2016 009 560 A1 discloses a LECO system. This system comprises an upper contact apparatus for making electrical contact with the front contact of the solar cell, a lower contact apparatus for making electrical contact with the rear contact of the solar cell and an electrical voltage source in order to apply a defined voltage to the solar cell and to regulate the current flow between the upper contact apparatus and the lower contact apparatus. This system is applied to a stationarily contacted solar cell, wherein a single roller or a brush is guided along the stationary solar cell in order to apply voltage to the solar cell. Furthermore, a point light source is guided over the front side of the solar cell when the voltage is applied, as a result of which a light-induced current flow is generated.

Furthermore, EP 1 997 157 B1 discloses a method for producing a photovoltaic element with stabilized efficiency, in which a silicon substrate provided with an emitter layer and front and rear contacts is kept at a temperature of between 5° and 230° C. and a voltage is applied to its contacts over a treatment period. As an alternative, a method is furthermore proposed in which a silicon substrate provided with an emitter layer is kept at a temperature of between 5° and 230° C. and illuminated over a treatment period that depends on both the temperature and the illuminance, and then the front contact and the rear contact are generated.

There is also a need to provide a solar cell that is in a significantly improved state in terms of its lifetime of mass recombination, surface recombination speed, and the contact resistance between metal and semiconductor and its regeneration, in order to increase and/or stabilize its efficiency.

### SUMMARY

It is therefore an object of the invention to provide a system and a method that are designed to provide a solar cell with an improved and/or stabilized efficiency.

According to the invention, this object is achieved by a system having the features of patent claim 1 and a method having the features of patent claim 6. Advantageous modifications and developments are specified in the dependent claims.

The efficiency of the solar cell is stabilized and/or improved by the heating apparatus and the additional heating of the solar cell to which voltage is applied during the local illumination and scanning. To date, separate processes have been integrated in a common method step and combined in an appropriately designed device.

According to the invention, provision is made in the system for a heating apparatus to be additionally provided, which is designed and configured to heat the solar cell during a current flow induced in the reverse direction. The heating apparatus is in particular in the form of a heatable element.

In one preferred embodiment, the heating apparatus is a thermally conductive plate. The plate is preferably a metal plate. The heating apparatus preferably has two thermally conductive plates, which are designed in such a way that they completely cover the front side and the rear side of the solar cell when they are arranged on the solar cell. This ensures uniform heating of the solar cell. The heating apparatus preferably further comprises a heating element or is coupled to a heating element so that the thermally conductive plate is able to be heated. Furthermore, the thermally conductive plate is preferably designed to be able to be coupled to a voltage source.

The contacting apparatuses of the voltage source may be connected directly to the front contact or the rear contact of the solar cell. Alternatively, the contacting apparatuses of the voltage source may also be connected to the front contact or the rear contact of the solar cell indirectly via electrically conductive components such as the metal plates.

Alternatively and/or additionally, the heating apparatus is preferably a bias light source. The bias light source is designed to simultaneously emit heat when the illumination is activated.

In one preferred embodiment, the heating apparatus is a heating chamber that comprises a chamber wall section transparent to visible light. The heating chamber is preferably designed so that the air located therein is able to be heated. A chamber wall section is preferably transparent to visible light and/or infrared radiation, so that the illumination unit can be arranged outside of the heating chamber when it illuminates the solar cell. By way of example, the chamber wall section that is transparent to visible light and infrared radiation is in the form of a window, preferably a glass window, more preferably a sapphire glass window, which is integrated in a chamber wall that is not transparent to visible light and infrared radiation. However, the chamber wall section may also constitute a complete chamber wall of the heating chamber. The heating chamber may be designed to accommodate the solar cell in a stationary manner. Alternatively, the heating chamber is designed to accommodate the solar cell in an inline process.

Preferably, the illumination unit is a point light source, even more preferably a laser apparatus.

Alternatively or additionally the illumination unit is preferably a bias light source. The bias light source preferably comprises an IR emitter. In this case, the bias light source simultaneously constitutes the heating apparatus and the illumination unit, but comprises appropriate optics to ensure both functionalities. The bias light source preferably comprises light-emitting diodes and/or halogen lamps.

In one preferred embodiment, the voltage source is designed to apply a voltage in the range of −12 to −20 volts to the solar cell. Preferably, the illumination unit is designed to illuminate the solar cell with an illuminance of 5 to 10000 suns (1 sun=1000 W/m² incident power density in the AM1.5G spectrum).

The system may be designed to accommodate the solar cell in a stationary manner or in an inline process. The solar cell is preferably a wafer solar cell.

The invention also relates to a method for stabilizing and/or improving an efficiency of a solar cell, comprising the following steps
a) providing a solar cell with a front-side front contact and a rear-side rear contact,
b) applying a voltage to the provided solar cell in the reverse direction,
c) heating the front side and the rear side of the solar cell to which the voltage is applied and simultaneously locally illuminating and scanning the front side of the solar cell to which the voltage is applied in such a way that a current flow flows through the solar cell in the reverse direction.

The following method parameters have proven to be advantageous:

In one preferred embodiment, a voltage in the range of −12 to −20 volts is applied to the solar cell in step b). Preferably, the solar cell is illuminated locally with an illuminance of 5 to 10000 suns (1 sun=1000 W/m² incident power density in the AM1.5G spectrum) in step c). In one preferred embodiment, the solar cell is heated to a temperature in the range of 100 to 1000° C., preferably 130 to 800° C., even more preferably 150 to 750° C., in step c). Preferably, the heating of the front side and the rear side of the solar cell to which the voltage is applied is carried out according to step c) over a time period of 1 to 30 seconds, preferably 1 to 20 seconds, more preferably 1 to 10 seconds. Preferably, the local illumination and scanning of the front contacts on the front side of the solar cell to which the voltage is applied is carried out according to step c) over a further time period of 1-2 seconds, preferably 1 second. The local illumination is preferably carried out in such a way that the solar cell is scanned over the whole surface.

### BRIEF DESCRIPTION OF THE DRAWINGS

The invention is illustrated below on the basis of exemplary embodiments with reference to the figures, in which, in each case schematically and not to scale:

FIG. 1 shows a cross-sectional view of a system according to the invention;

FIG. 2 shows a cross-sectional view of a further system according to the invention; and

FIG. 3 shows a flowchart of a method according to the invention.

### DETAILED DESCRIPTION

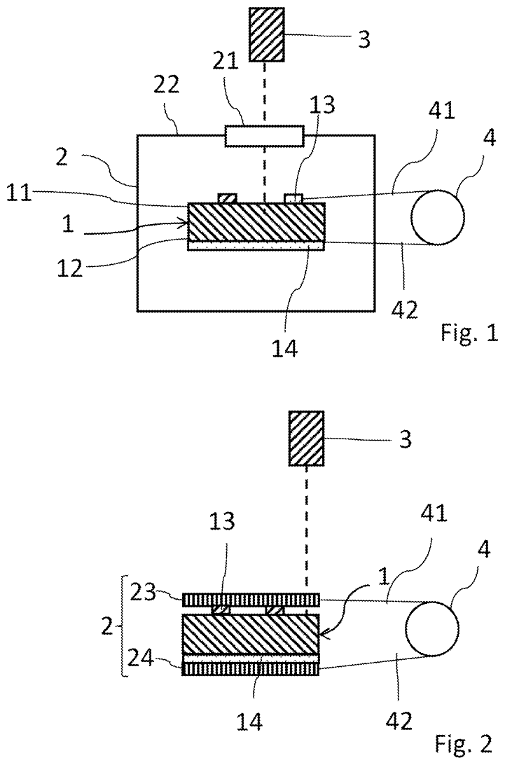

FIG. 1 shows a cross-sectional view of a system according to the invention. The system is designed to stabilize and/or improve an efficiency of a solar cell 1 having a front side 11 and a rear side 12. The solar cell 1 comprises, on its front side 11, a front contact 13, for example in the form of finger electrodes, and on its rear side 12, a rear contact 14 formed over the whole surface thereof. The system has an illumination unit 3, which is designed to illuminate the solar cell 1, in particular its front side 11, both locally and extensively. Purely by way of example, the illumination unit comprises a laser apparatus for the local illumination, which is designed to emit a laser beam, as indicated by the dotted line. The laser beam interacts with the entire pattern of the front-contact finger electrodes within a few seconds or fractions of a second. Furthermore, the illumination unit 3 also comprises illuminants to preferably illuminate the whole surface of the solar cell 1. These additional illuminants are, for example, in the form of halogen bulbs or LED illuminants. Furthermore, the system comprises a voltage source 4 having two contacting apparatuses 41, 42. One contacting apparatus 41 is designed to be connected to the front contact 13 of the solar cell 1, and the other contacting apparatus 42 is designed to be connected to the rear contact 14 of the solar cell 1 in such a way that a current flow is induced in the reverse direction of the solar cell 1. The system furthermore additionally comprises a heating apparatus 2, which is designed and configured to heat the solar cell 1 during a current flow induced in the reverse direction. The heating apparatus 2 is in the form of a heating chamber, which heats the solar cell 1 using hot air, for example. The heating apparatus 2 comprises a chamber wall section 21, which is transparent to visible light, in the form of a window that is integrated in a chamber wall 22 that is not transparent to visible light. Due to the window, the illumination apparatus may be arranged outside of the heating apparatus 2 and still illuminate the solar cell 1 with local scanning and over the whole surface.

FIG. 2 shows a cross-sectional view of a further system according to the invention. The system shown in FIG. 2 corresponds to the system shown in FIG. 1, with the difference that the heating apparatus 2 is not in the form of a heating chamber but is in the form of two thermally conductive plates 23, 24, which are able to be heated during operation and are arranged on the front-side contact 13 or the rear-side contact 14 of the solar cell 1 such that they cover the whole surface of the solar cell 1 and transfer heat thereto. Furthermore, the thermally conductive plates 23, 24 are designed to be electrically conductive. One contacting apparatus 41 is electrically connected to the front contact 13 via the plate 23, while the other contacting apparatus 42 is electrically connected to the rear contact 14 via the plate 24.

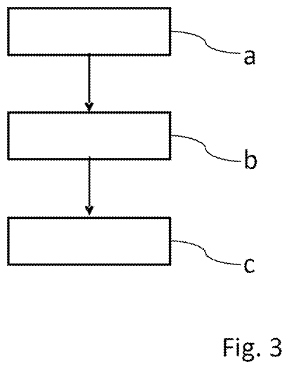

FIG. 3 shows a flowchart of a method according to the invention. The method is used to stabilize and/or improve an efficiency of a solar cell and may be carried out, for example, in the system shown in FIG. 1 or 2. The method comprises a step a) of providing a solar cell with a front-side front contact and a rear-side rear contact, a step b) of applying a voltage to the provided solar cell in the reverse direction, and a step c) of heating the front side and the rear side of the solar cell to which the voltage is applied and simultaneously locally illuminating and scanning the front side of the solar cell to which the voltage is applied in such a way that a current flow flows through the solar cell in the reverse direction.

A voltage in the range of −12 to −20 volts may be applied to the solar cell in step b). Furthermore, the solar cell may be illuminated locally with an illuminance of 5 to 10000 suns (1 sun=1000 W/m² incident power density in the AM1.5G spectrum) in step c). In addition, the solar cell may be heated to a temperature in the range of 150 to 850° C. in step c). The heating of the front side and the rear side of the solar cell to which the voltage is applied may be carried out according to step c) over a time period of 5 to 10 seconds, whereas the local illumination and scanning of the front side of the solar cell to which the voltage is applied may be carried out according to step c) over a time period of 1 second.

### LIST OF REFERENCE SIGNS

1 solar cell
11 front side
12 rear side
13 front contact
14 rear contact
2 heating apparatus
21 chamber wall section
22 further chamber wall section
23 plate
24 further plate
3 illumination unit
4 voltage source
41 contact apparatus
42 other contact apparatus

1. A system for stabilizing and/or improving an efficiency of a solar cell having a front-side front contact and a rear-side rear contact, the system comprising:
an illumination unit that is designed to locally illuminate the solar cell,
a voltage source having two contacting apparatuses, wherein one contacting apparatus is designed to be connected to the front contact of the solar cell, and the other contacting apparatus is designed to be connected to the rear contact of the solar cell in such a way that a current flow is induced in the reverse direction of the solar cell, and
a heating apparatus which is designed and configured to heat the solar cell during the current flow induced in the reverse direction.

2. The system according to claim 1, wherein the heating apparatus is a thermally conductive plate and/or a bias light source.

3. The system according to claim 1, wherein the heating apparatus is a heating chamber that comprises a chamber wall section transparent to visible light and/or infrared radiation.

4. The system according to claim 1, wherein the illumination unit is a laser and/or a bias light source.

5. The system according to claim 1, wherein the voltage source is designed to apply a voltage in the range of −12 to −20 volts to the solar cell and/or the illumination unit is designed to illuminate the solar cell with an illuminance of 5 to 10000 suns wherein 1 sun=1000 W/m² incident power density in the AM1.5G spectrum.

6. A method for stabilizing and/or improving an efficiency of a solar cell, comprising the following steps:
a) providing a solar cell with a front-side front contact and a rear-side rear contact,
b) applying a voltage to the provided solar cell in the reverse direction,
c) heating the front side and the rear side of the solar cell to which the voltage is applied and simultaneously locally illuminating and scanning the front side of the solar cell to which the voltage is applied in such a way that a current flow flows through the solar cell in the reverse direction.

7. The method according to claim 6, wherein a voltage in the range of −12 to −20 volts is applied to the solar cell in step b).

8. The method according to claim wherein the solar cell is illuminated locally with an illuminance of 5 to 10000 suns, wherein 1 sun=1000 W/m² incident power density in the AM1.5G spectrum, in step c).

9. The method according to claim 6, wherein the solar cell is heated to a temperature in a range of 150 to 850° C. in step c).

10. The method according to claim 6, wherein the heating of the front side and the rear side of the solar cell to which the voltage is applied is carried out according to step c) over a time period of 1 to 30 seconds.

11. The method according to claim 6, wherein the heating of the front side and the rear side of the solar cell to which the voltage is applied is carried out according to step c) over a time period of 1 to 20 seconds.

12. The method according to claim 6, wherein the heating of the front side and the rear side of the solar cell to which the voltage is applied is carried out according to step c) over a time period of 1 to 10 seconds.
